(19) United States
(12) Patent Application Publication
(10) Pub. No.: US 2025/0372535 A1
(43) Pub. Date: Dec. 4, 2025

(54) PROTECTIVE MOISTURE BARRIER AND CRACK STOP STRUCTURE FOR IC CHIP USING AIR GAP IN LINER IN DEEP TRENCH

(71) Applicant: GlobalFoundries Singapore Pte. Ltd., Singapore (SG)

(72) Inventors: Xiaodong Li, Singapore (SG); Wanbing Yi, Singapore (SG); Weichu Qiu, Singapore (SG)

(21) Appl. No.: 18/731,564

(22) Filed: Jun. 3, 2024

(51) Int. Cl. H01L 23/00; H01L 21/768; H01L 23/532; H01L 23/58

(52) U.S. Cl. CPC H01L 23/562; H01L 21/7682; H01L 23/53295; H01L 23/564; H01L 23/585

(57) ABSTRACT

A structure includes an integrated circuit (IC) chip including an IC region and a peripheral region around the IC region. A first continuous deep trench (DT) is defined in the peripheral region around the IC region, and an air gap is defined by a first dielectric liner in the first continuous DT. The structure provides a moisture barrier and a crack stop.

### BACKGROUND

The present disclosure relates to integrated circuits and, more particularly, to a structure including a continuous deep trench having an air gap in a dielectric liner. The deep trench and air gap extend around an integrated circuit (IC) region of an IC chip to provide a moisture barrier and a crack stop.

IC chips can fail or be damaged when moisture enters the structure or cracks infiltrate the IC chip. Certain IC chips use metal seal rings that include stacked layers of metal wires and vias around the chip periphery to prevent moisture ingress and prevent crack propagation. IC chips that include radio frequency (RF) circuits require the use of a segmented metal seal ring, i.e., gaps in the ring, to prevent interference with RF circuit operation, such as signal coupling between the RF circuits. The gaps allow moisture penetration into the IC chip. Moisture barriers may also be provided by vertically-oriented dielectric layers that are typically combined with crack stops that include, similar to the metal seal rings, stacked layers of metal wires and vias around the chip periphery. In this situation, the crack stops may also interfere with RF circuit operation unless they are segmented.

### SUMMARY

All aspects, examples and features mentioned below can be combined in any technically possible way.

An aspect of the disclosure provides a structure, comprising: an integrated circuit (IC) chip including an IC region and a peripheral region around the IC region; a first continuous deep trench (DT) defined in the peripheral region around the IC region; and an air gap defined by a first dielectric liner in the first continuous DT.

An aspect of the disclosure relates to a protective moisture barrier and crack stop structure for an integrated circuit (IC) chip including an IC region, a peripheral region around the IC region and a back-end-of-line (BEOL) interconnect stack in the IC chip, the structure comprising: a first continuous deep trench (DT) defined in the peripheral region around the IC region; and an air gap defined by a first dielectric liner in the first continuous DT, wherein the first continuous DT extends vertically along an entirety of the BEOL interconnect stack in the IC region, wherein the peripheral region is devoid of any other moisture barrier or crack stop structures.

An aspect of the disclosure provides a method, comprising: in a semiconductor substrate including a plurality of integrated circuit (IC) chips, each IC chip including an IC region and a peripheral region around the IC region, wherein the IC region includes a back-end-of-line (BEOL) interconnect stack: forming a first continuous deep trench (DT) defined in the peripheral region around the IC region, wherein the first continuous DT extends vertically along an entirety of the BEOL interconnect stack in the IC region; and forming a dielectric layer over the semiconductor substrate, the dielectric layer forming also forming an air gap in a first dielectric liner in the first continuous DT.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a structure providing a protective moisture barrier and crack stop structure for an IC chip according to embodiments of the disclosure.

FIG. 2 shows a schematic top-down view of the structure of FIG. 1.

FIG. 3 shows an enlarged cross-sectional view of a dielectric layer according to embodiments of the disclosure.

FIG. 4 shows a cross-sectional view of a structure including a plurality of protective structures according to embodiments of the disclosure.

FIG. 5 shows a schematic top-down view of the structure of FIG. 4.

FIG. 6 shows a cross-sectional view of a structure including, in addition to a protective structure, a second continuous deep trench (DT) according to embodiments of the disclosure.

FIG. 7 shows a cross-sectional view of a structure including a plurality of protective structures with a second continuous DT according to embodiments of the disclosure.

FIG. 8 shows a cross-sectional view of a structure including a protective structure and a segmented metal seal ring according to embodiments of the disclosure.

FIG. 9 shows a schematic top-down view of the structure of FIG. 8.

FIG. 10 shows a cross-sectional view of a structure including a protective structure and a segmented metal seal ring according to other embodiments of the disclosure.

FIG. 11 shows a schematic top-down view of the structure of FIG. 10.

FIG. 12 shows a cross-sectional view of a structure including a protective structure and a segmented metal seal ring according to other embodiments of the disclosure.

FIG. 13 shows a schematic top-down view of the structure of FIG. 12.

FIG. 14 shows a cross-sectional view of various steps of a method according to embodiments of the disclosure.

FIG. 15 shows a cross-sectional view of various steps of a method according to embodiments of the disclosure.

FIG. 16 shows a cross-sectional view of various steps of a method according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure including an integrated circuit (IC) chip including an IC region and a peripheral region around the IC region. The structure may include a protective moisture barrier and a crack stop structure (protective structure) including a first continuous deep trench (DT) defined in the peripheral region around the IC region, and an air gap defined by a first dielectric liner in the first continuous DT. The protective structures are not expensive to add and are advantageous for, for example, radio frequency (RF) circuit applications. The structures may also optionally include a seal ring and/or another open-ended deep trench.

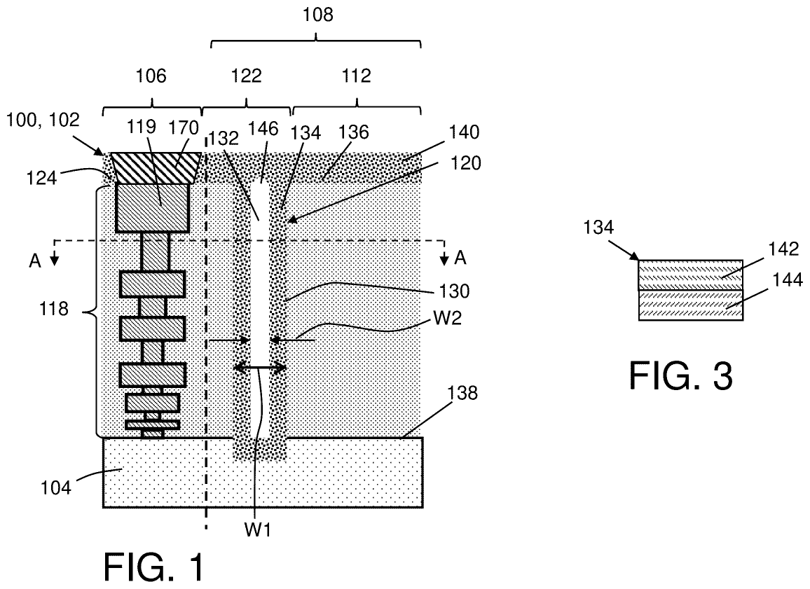

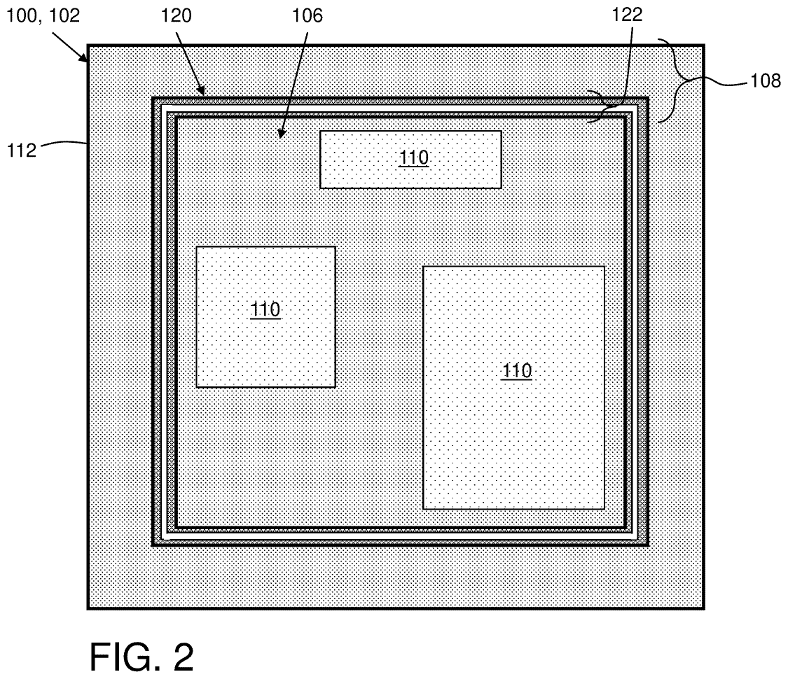

FIG. 1 shows a cross-sectional view of a structure 100 providing a protective moisture barrier and crack stop structure 120 for an IC chip 102, according to embodiments of the disclosure. FIG. 2 shows a schematic top-down view of structure 100 on IC chip 102 after singulation. (Note, the top-down views of FIGS. 3, 5, 9, 11 and 13 are schematic in that they show air gap(s) 132 as though cross-sectioned along a horizontal view line therethrough, like view line A-A in FIG. 1, but do not show any details of IC region 106, such as BEOL interconnect stack for clarity. Similarly, the cross-sectional views show only a view across one side of peripheral region 108 and do not show any details of RF circuits 110).

IC chip 102 may include any now known or later developed IC chip. IC chip 102 originates from a substrate 104 having a plurality of integrated circuit (IC) regions 106 thereon. In some embodiments, substrate 104 can include, but is not limited to: a bulk semiconductor substrate with front end of the line (FEOL) devices thereon; middle of the line (MOL) dielectric material on the FEOL devices; and contacts extending through the MOL dielectric material to one or more of the FEOL devices. In other embodiments, substrate 104 can include, but is not limited to: a semiconductor on insulator (SOI) structure with a semiconductor substrate, a buried insulator layer on the semiconductor substrate, and a semiconductor layer on the buried insulator layer; FEOL devices thereon; MOL dielectric material on the FEOL devices; and contacts extending through the MOL dielectric material to one or more of the FEOL devices. To avoid clutter in the figures and allow the reader to focus on the salient aspects of the disclosed embodiments, the layers of substrate 104 have been omitted to allow the reader to focus on the salient aspects of the disclosed embodiments.

Each IC region 106 includes any variety of active integrated circuitry including transistors (not shown, but on or in upper surface of substrate 104) and other integrated circuit devices. In certain embodiments, the teachings of the disclosure are advantageous for IC regions 106 including one or more radio frequency (RF) circuits 110. While three RF circuits 110 are shown, any number may be used, including none. IC chip 102 also includes a back-end-of-line (BEOL) interconnect stack 118 on substrate 104 (i.e., above the MOL dielectric material and contacts therein). BEOL interconnect stack 118 may include a plurality of metal layers and a plurality of via layers formed over a device layer. Each metal layer includes a mainly laterally extending conductive wire(s) or line(s) in an insulator layer, and each via layer includes a mainly vertically extending conductive pillar(s) in an insulator layer. As understood in the field, BEOL interconnect stack 118 electrically couples and scales portions of IC circuitry of IC chip 102 starting at a device layer and extending up to a last metal layer 119 for electrical connection within and without IC chip 102.

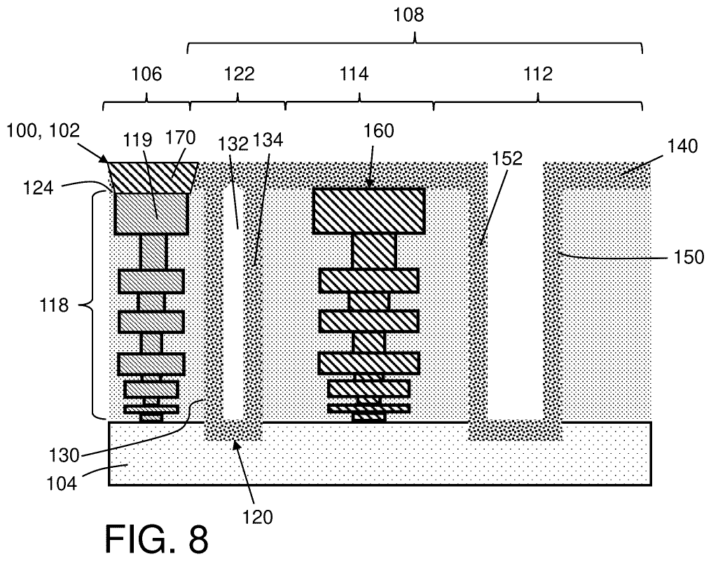

IC chip 102 also includes a peripheral region 108 around IC region 106. More particularly, peripheral region 108 surrounds IC region 106. Peripheral region 108 includes the same insulator layers (not separately shown) as BEOL interconnect stack 118, but the conductive parts of BEOL interconnect stack 118 do not extend into peripheral region 108. As understood in the field, after manufacture of hundreds, perhaps thousands, of IC chips 102 on substrate 104 (e.g., wafer), the plurality of IC chips 102, each with their own IC region 106, are separated at a scribe region 112 (also known as a kerf region) of peripheral region 108 surrounding each IC region 106. More particularly, a dicing tool (not shown) cuts IC chips 102 apart from each other and from the rest of substrate 104. The dicing tool may include any now known or later developed tool, such as a laser, to separate IC chips 102. Scribe region 112 may also include any variety of test structures (not shown) to test IC chip 102. As understood in the field, the test structures are typically removed during the dicing of IC chips 102. As will be described herein, and as shown in FIG. 8, structure 100 may optionally include a seal ring region 114 adjacent scribe region 112. As shown in FIG. 2, only a remnant of scribe region 112 remains around IC region 106 in IC chip 102 after dicing.

Structure 100 also includes a protective moisture barrier and crack stop structure 120 (hereafter “protective structure 120” for brevity) in a protection region 122 within peripheral region 108. Protection region 122 is inward of scribe region 112 such that protective structure 120 remains part of IC chip 102 after dicing. Protective structure 120 includes a first continuous deep trench (DT) 130 defined in peripheral region 108 around IC region 106, and an air gap 132 defined by a first dielectric liner 134 in first continuous DT 130. As used herein, “continuous” indicates deep trench 130 (and air gap 132 therein) extends around IC region 106 in an uninterrupted manner, i.e., it/they are not segmented and do not include any interruptions therein. First continuous DT 130 also extends vertically from an upper surface 136 of the BEOL insulator layers in peripheral region 108 below the level of the bottom surface of BEOL interconnect stack 118. Hence, first continuous DT 130 extends vertically along an entirety of BEOL interconnect stack 118 in IC region 106. As shown in FIG. 1, first continuous DT 130 may also extend at least partially into an upper surface 138 of substrate 104. For example, first continuous DT 130 could extend partially into the MOL dielectric material of substrate 104. Alternatively, first continuous DT 130 could extend completely through MOL dielectric material of substrate 104. Alternatively, first continuous DT 130 could extend below FEOL devices of substrate 104 (e.g., in the case of a bulk semiconductor structure, partially through the bulk semiconductor substrate or in the case of an SOI structure to the buried insulator layer, through the buried insulator layer, or even into the semiconductor substrate below the buried insulator layer). In certain embodiments, first continuous DT 130 may have a maximum width W1, excluding first dielectric liner 134, in a range of 1.0 to 1.5 micrometers.

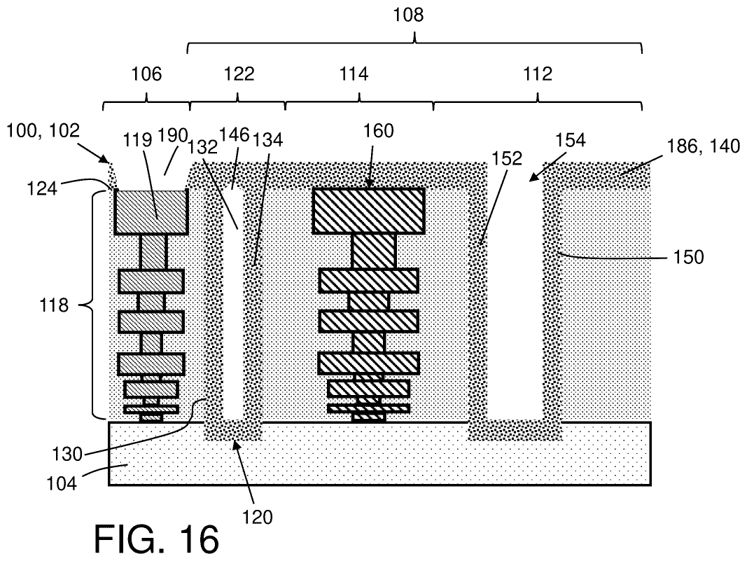

As noted, air gap 132 is defined by first dielectric liner 134 in first continuous DT 130. First dielectric liner 134 may include any now known or later developed dielectric materials configured to also be used as a passivation layer 140 over upper surface 124 of IC region 106 and upper surface 136 of peripheral region 108. In certain embodiments, first dielectric liner 134 may include a single layer of material, such as silicon nitride. In other embodiments, as shown in an enlarged cross-sectional view in FIG. 3, first dielectric liner 134 may include multiple layers, such as a silicon nitride layer 142 over a silicon oxide layer 144. Other dielectric material options are also possible. In any event, first dielectric liner 134 is impenetrable by moisture, e.g., water, and thus provides a double layered moisture barrier (both sides of first continuous DT 130) for IC chip 102. Silicon nitride layer 142, in particular, is water impenetrable. As will be described herein, first dielectric liner 134 may be formed during the same deposition process as passivation layer 140, which includes the same materials and layers. Continuous DT 130 has a sufficiently small maximum width W1 such that the dielectric(s) deposition results in the dielectric(s) forming on sidewalls and bottom of first continuous DT 130, creating first dielectric liner 134 and passivation layer 140. In addition, the dielectric(s) eventually pinch off an upper end of first continuous DT 130 to form air gap 132. In this manner, first dielectric liner 134 is contiguous with passivation layer 140 over IC chip 102, and air gap 132 has an upper end 146 (labeled in FIGS. 1 and 16 only) at least covered by passivation layer 140. Based on the stated maximum width W1 of first continuous DT 130 and the illustrative dielectric(s) listed herein, air gap 132 has a maximum width W2 in a range of 0.2 to 0.5 micrometers.

Air gap 132 extends continuously around IC region 106 of IC chip 102 in first continuous DT 130, i.e., it is continuous just like the deep trench. Air gap 132 provides a crack stop function for any crack that may propagate from, for example, scribe region 112 during dicing or other processing. More particularly, air gap 132 provides a void or empty space through which stresses that cause cracking cannot transmit. Air gap 132 may have a height (vertically on page) that is substantially the same to first continuous DT 130, and thus has substantially the same height as BEOL interconnect stack 118 in IC region 106. As used here relative to the height of air gap 132, “substantially” means+/−0.5 to 1 micrometer. Thus, air gap 132 extends vertically along close to, if not all of, the entirety of BEOL interconnect stack 118 in IC region 106. In this manner, air gap 132 prevents crack propagation into IC region 106 regardless of the depth at which a crack may transmit through peripheral region 108 and removes any guess work as to what depth to put a crack stop structure.

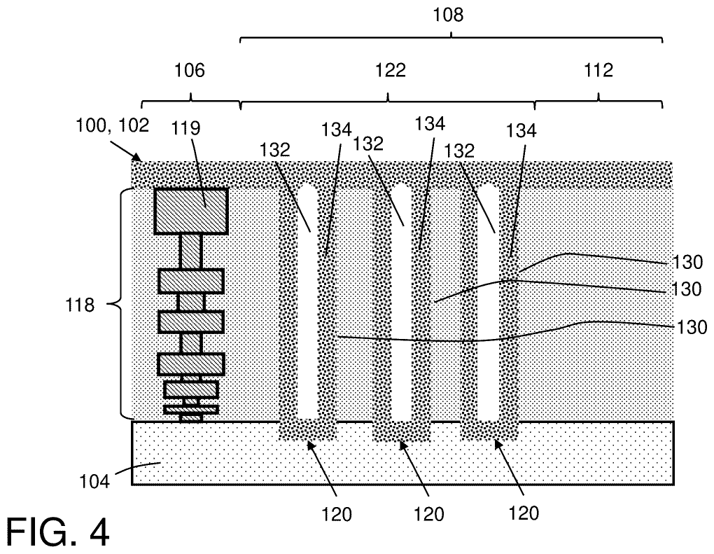

FIGS. 4-13 show cross-sectional or schematic top-down views of alternative embodiments of structure 100 including protective structure 120.

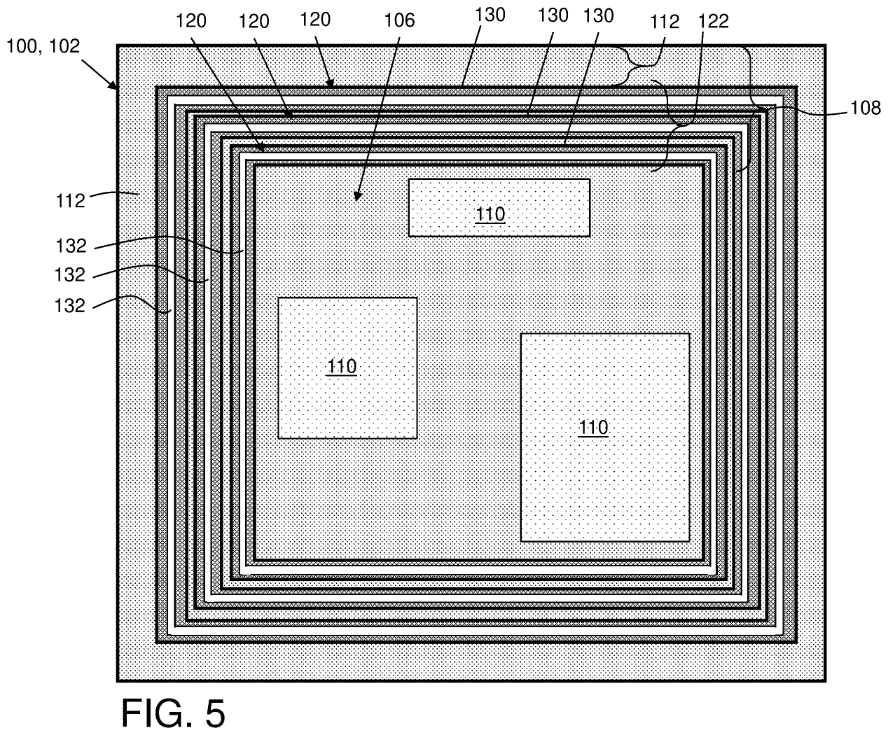

FIG. 4 shows a cross-sectional view and FIG. 5 shows a schematic top-down view of structure 100 including a plurality of protective structures 120 in peripheral region 108. Protective structures 120 are concentrically arranged. More particularly, first continuous DT 130 includes a plurality of first continuous DTs 130 that are concentrically arranged. Each first continuous DT 130 includes a corresponding air gap 132 in first dielectric liner 134 therein; hence, air gaps 132 are also concentrically arranged. This arrangement provides numerous moisture barriers and crack stops in an easy to manufacture and cost-effective manner. While three protective structures 120 are shown, any number may be used so long as sufficient space in peripheral region 108 is available. In the FIGS. 1-5 embodiments, peripheral region 108 is devoid of any other moisture barrier or crack stop structures other than protective structure(s) 120, i.e., air gap 132 in first dielectric liner 134.

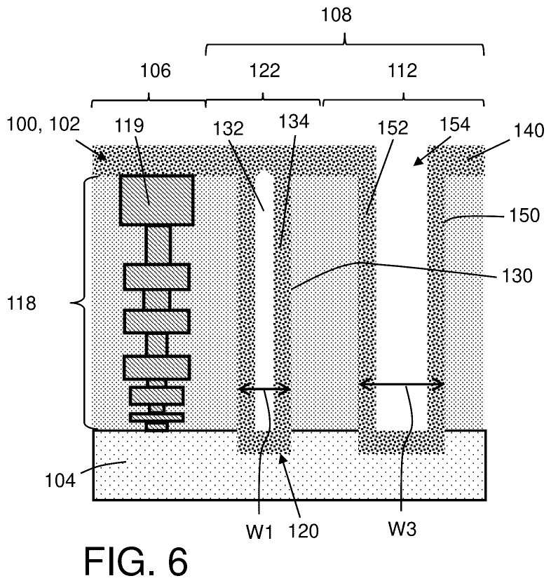

FIG. 6 shows a cross-sectional view of structure 100 including, in addition to protective structure 120, a second continuous deep trench (DT) 150 defined in scribe region 112 of peripheral region 108 around first continuous DT 130 and air gap 132. Structure 100 also includes a second dielectric liner 152 in second continuous DT 150. Second continuous DT 150, however, is wider than any first continuous DT 130. For example, where first continuous DT 130 has maximum width W1, excluding first dielectric liner 134, in a range of 1.0 to 1.5 micrometers, and second continuous DT 150 may have a maximum width W3, excluding second dielectric liner 152, in a range of 6 to 30 micrometers. (Note again, the drawings are not to scale). Hence, first continuous DT 130 has a maximum width W1 smaller than that of second continuous DT 150, i.e., maximum width W3. Further, second dielectric liner 152 does not pinch off second continuous DT 150 and it has an open upper end 154 (FIG. 6 only). Second dielectric liner 152 may include the same dielectric(s) as first dielectric liner 134 and passivation layer 140. Consequently, as previously described, in certain embodiments, second dielectric liner 152 may include a single layer of material, such as silicon nitride or, as shown in FIG. 3, second dielectric liner 152 may include multiple layers, such as silicon nitride layer 142 over silicon oxide layer 144. Other dielectric material options are also possible. As will be described herein, second dielectric liner 152 may be formed during the same deposition process as first dielectric liner 134 in first continuous DT 130 and passivation layer 140. Second continuous DT 150 aids in subsequent dicing, e.g., in a laser groove-free dicing method. After dicing, the outward facing sidewall of second continuous DT 150 with second dielectric liner 152 thereon may remain, providing additional protection against moisture ingress and/or cracking.

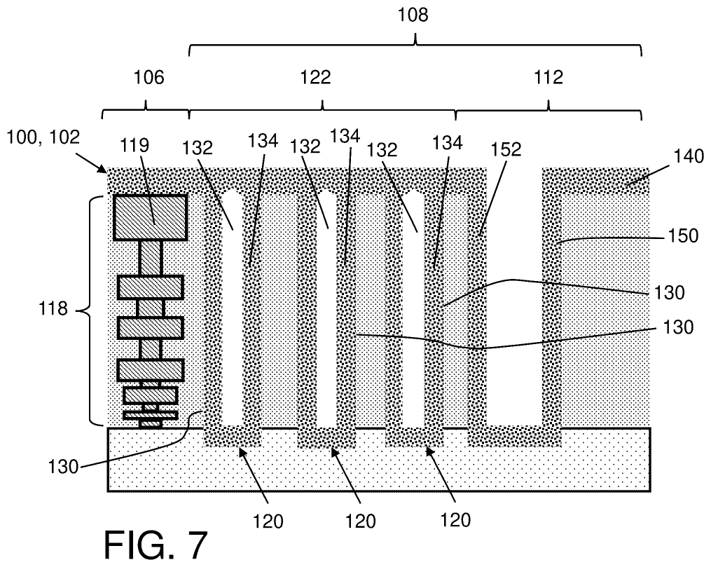

FIG. 7 shows a cross-sectional view of structure 100 including a plurality of protective structures 120, each with a respective first continuous DT 130 and air gap 132, and with second continuous DT 150, as described relative to FIG. 6.

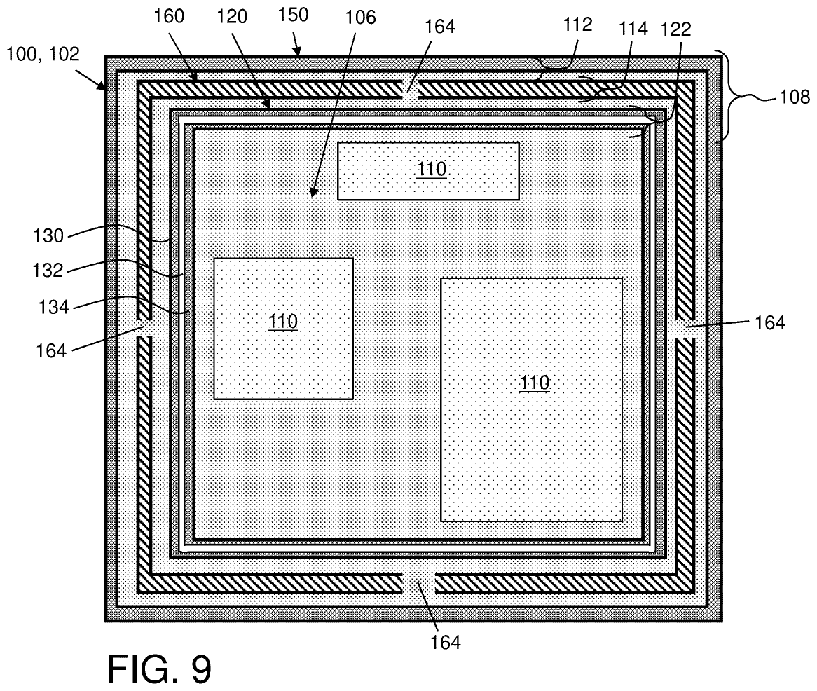

FIG. 8 shows a cross-sectional view and FIG. 9 shows a schematic top-down view of structure 100 including protective structure 120 as arranged in FIG. 1, but also including a segmented metal seal ring 160 between protective structure 120 (i.e., with first continuous DT 130, air gap 132 and first dielectric liner 134) and second continuous DT 150 (i.e., with second dielectric liner 152). Hence, segmented metal seal ring 160 is between first continuous DT 130 and second continuous DT 150. Segmented metal seal ring 160 is in seal ring region 114 of peripheral region 108, which is, as shown in FIG. 8, between protection region 122 with protective structure 120 therein and scribe region 112 with second continuous DT 150 therein. Segmented metal seal ring 160 surrounds protective structure 120 and may be concentric therewith excepting where segmented. Segmented metal seal ring 160 may include any now known or later developed metal seal ring structure. As shown, segmented metal seal ring 160 includes a plurality of metal layers and a plurality of via layers. Each metal layer includes a mainly laterally extending conductive wire(s) or line(s) in an insulator layer, and each via layer includes a mainly vertically extending conductive pillar(s) in an insulator layer. As understood in the field, segmented metal seal ring 160 is not electrically active, i.e., there is no electric current running therein.

As shown in FIG. 9, segmented metal seal ring 160 may be segmented in that it is not continuous around IC region 106 and includes one or more (four shown) breaks 164 filled with dielectric, i.e., the dielectric layers of peripheral region 108 and BEOL interconnect stack 118 in IC region 106. In this manner, segmented metal seal ring 160 advantageously provides the desired functioning of such a ring, e.g., preventing the RF signal coupling between RF circuits 110, but the moisture penetration exhibited by such segmented metal seal rings 160 is prevented by protective structure 120. Where segmented metal seal ring 160 is not used, the unused space can be removed or used for other purposes.

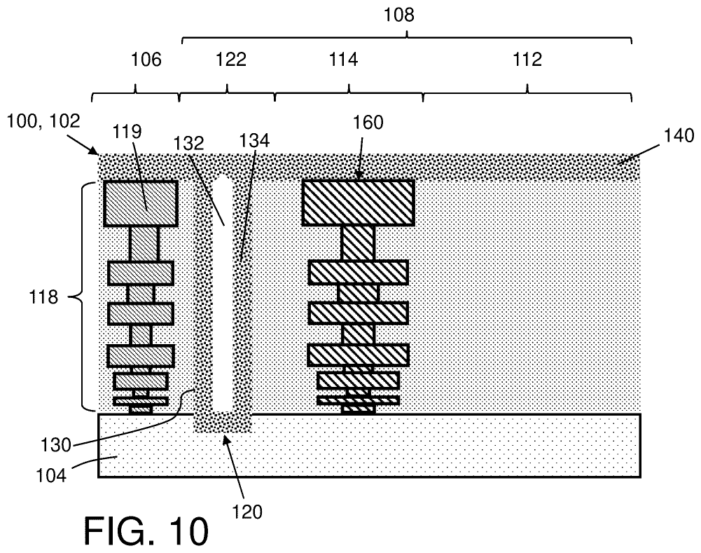

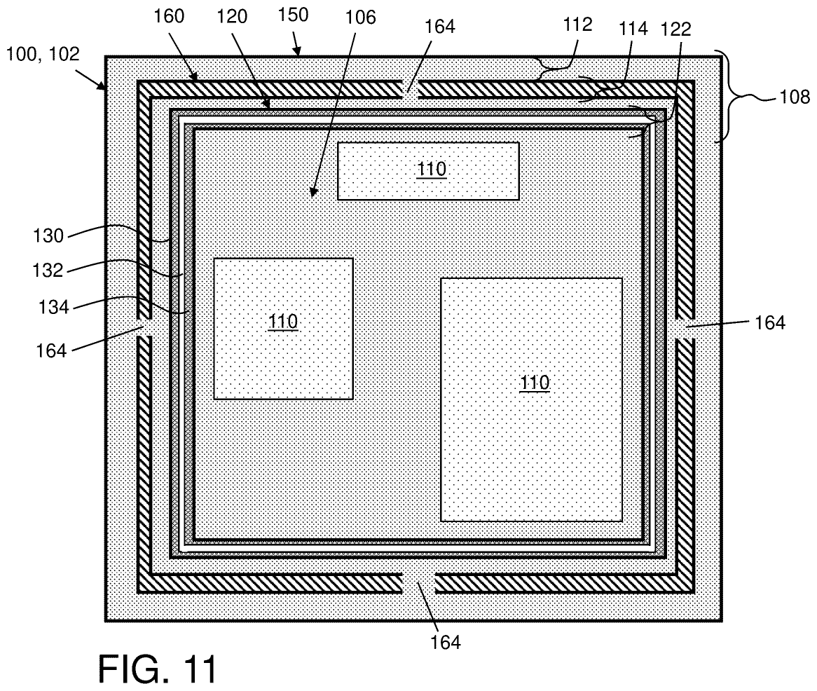

FIG. 10 shows a cross-sectional view and FIG. 11 shows a schematic top-down view of structure 100 including protective structure 120 and segmented metal seal ring 160, as arranged in FIG. 8, but excluding second continuous DT 150 (FIG. 8) in scribe region 112.

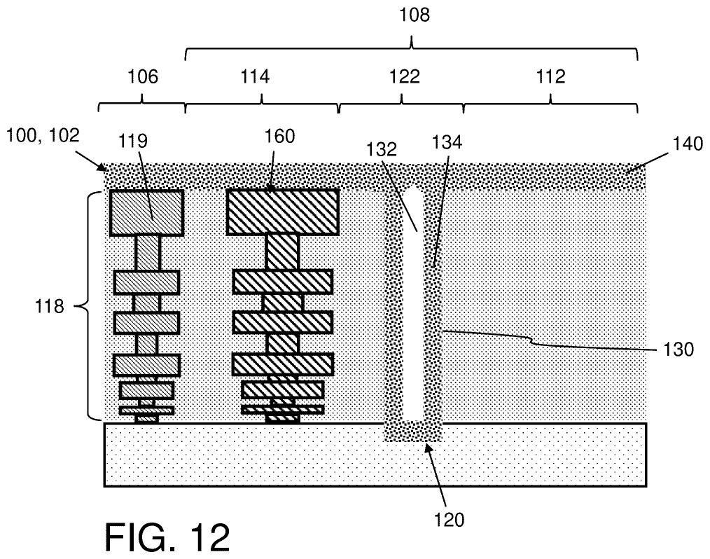

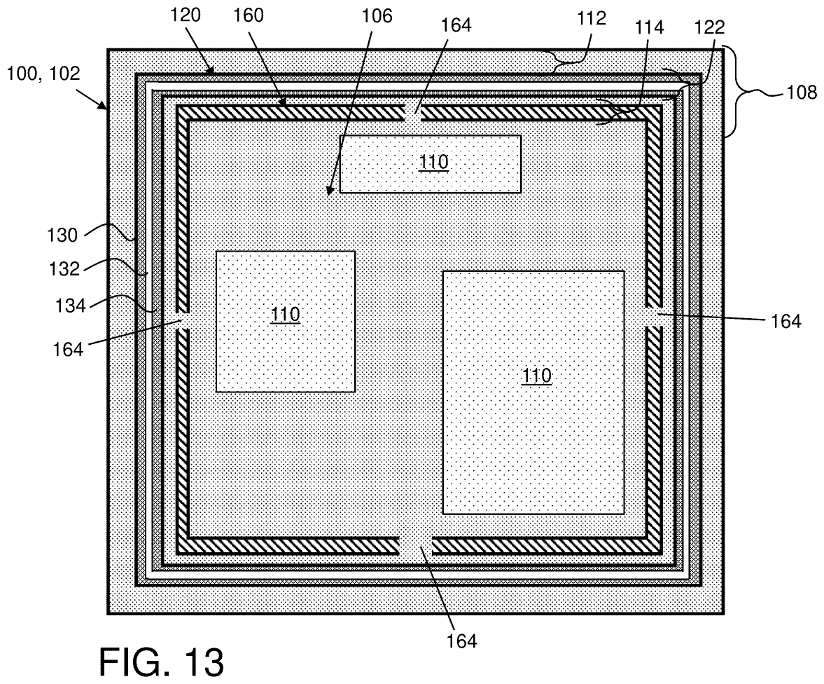

FIG. 12 shows a cross-sectional view and FIG. 13 shows a schematic top-down view of structure 100 with protective structure 120 and segmented metal seal ring 160, as in FIGS. 10 and 11, but switched in position. That is, segmented metal seal ring 160 surrounds IC region 106, and protective structure 120 with first continuous DT 130, air gap 132 and first dielectric liner 134, surrounds segmented metal seal ring 160.

As described herein, protective structure 120, i.e., a protective moisture barrier and crack stop structure, for IC chip 102 is provided. IC chip 102 includes IC region 106, peripheral region 108 around IC region 106 and BEOL interconnect stack 118 in IC chip 102. Protective structure 120 includes first continuous DT 130 defined in peripheral region 108 around IC region 106, and air gap 132 defined by first dielectric liner 134 in first continuous DT 130. First continuous DT 130 extends vertically along an entirety of BEOL interconnect stack 118 in IC region 106. As shown in FIGS. 1-4, peripheral region 108 may be devoid of any other moisture barrier and/or crack stop structures than protective structure 120.

Referring to FIG. 1, structure 100 may also include a conductive member 170 at an upper surface 124 of IC region 106 and in contact with last metal layer 119 of BEOL interconnect stack 118. Conductive member 170 may include a conductive wire or line in contact with last metal layer 119 of IC region 106. Contact pads (not shown) may be made over conductive member 170.

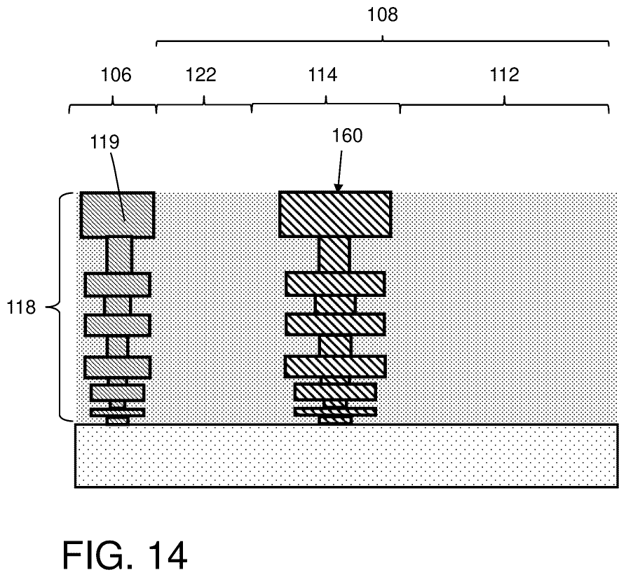

FIGS. 14-16 show cross-sectional views of a method according to embodiments of the disclosure. For purposes of description, the method will be described relative to the FIG. 8 embodiment. It will be recognized that the other embodiments described herein can be made by similar methods applied in different locations on substrate 104.

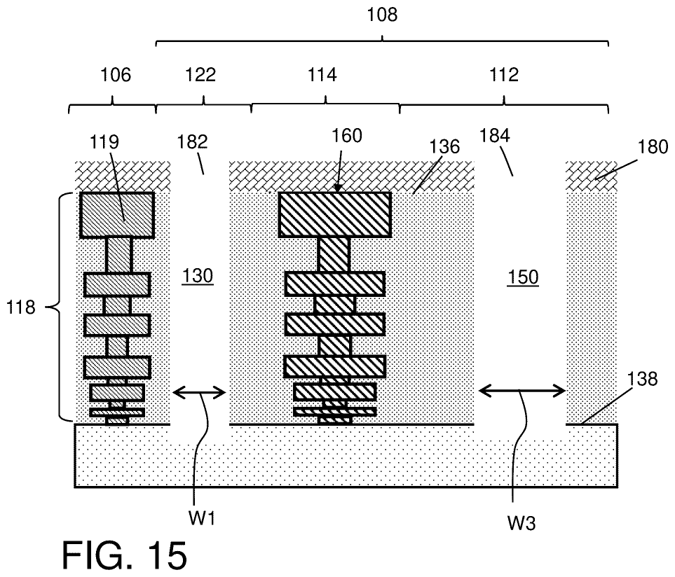

FIG. 14 shows processing after formation of IC chip 102 according to any now known or later developed semiconductor fabrication techniques such as but not limited to photolithography, deposition, and doping. As understood in the art, fabrication on or in substrate 104 includes forming a plurality of IC chips 102. Each IC chip 102 includes IC region 106, including integrated circuitry, and peripheral region 108 around IC region 106 without active circuitry of IC chip 102 therein. Forming IC region 106 also includes forming BEOL interconnect stack 118 using any now known or later developed BEOL fabrication techniques. FIG. 14 also shows the optional forming of segmented metal seal ring 160. Segmented metal seal ring 160 will eventually be between first continuous DT 130 and second continuous DT 150—see FIG. 15. Segmented metal seal ring 160 may be formed using the same techniques (and at the same time) as BEOL interconnect stack 118, except segmented metal seal ring 160 extends around IC region 106 and, as shown for the FIG. 8 embodiment, first continuous DT 130. As the details of the fabrication techniques up to this stage are well known, no further detail is necessary to enable one with skill in the art to practice this part of the disclosure.

As shown in FIG. 15, the method may also include forming first continuous DT 130 defined in peripheral region 108 around IC region 106. First continuous DT 130 may be formed using any desired photolithography processing, e.g., forming and patterning a mask and etching to remove material. For example, first continuous DT 130 may be formed by forming and then patterning a mask 180 to have an opening 182, and then etching first continuous DT 130 to the desired depth. Opening 182 extends around IC region 106 in a continuous manner. First continuous DT 130 extends from substrate 104 to upper surface 136 of the insulator layers of peripheral region 108. Hence, first continuous DT 130 extends vertically along an entirety of BEOL interconnect stack 118 in IC region 106. As shown in FIG. 14, first continuous DT 130 may also extend partially into upper surface 138 of substrate 104. In certain embodiments, first continuous DT 130 may have a maximum width W1 in a range of 1.0 to 1.5 micrometers. Where more than one protective structure 120 is to be used, the method may include forming a plurality of first continuous DTs 130 that are concentrically arranged-see FIGS. 4 and 7. This process would include providing additional openings 182 concentrically arranged in mask 180 that extend around IC region 106.

As also shown in FIG. 15, the method may optionally include forming second continuous DT 150 defined in peripheral region 108, i.e., in scribe region 112 thereof, around first continuous DT 130. Second continuous DT 150 may be formed in the same manner as (and at the same time as) first continuous DT 130, except an opening 184 in mask 180 for second continuous DT 150 is larger than opening 182 for first continuous DT 130. Second continuous DT 150 extends from substrate 104 to upper surface 136 of the insulator layers of peripheral region 108. Hence, second continuous DT 150 extends vertically along an entirety of BEOL interconnect stack 118 in IC region 106. As shown in FIG. 15, second continuous DT 150 may also extend partially into upper surface 138 of substrate 104. In certain embodiments, second continuous DT 150 may have maximum width W3 in a range of 6 to 30 micrometers.

First and second continuous DT 130, 150 forming may occur with deep trench formation in other parts of substrate 104 such as but not limited to through silicon via (TSV) formation and/or deep trench isolation formation in IC regions 106. Mask 180 may include any now known or later developed masking material appropriate for the etching chemistry used. In one example, mask 180 may include a silicon nitride hard mask. The etching chemistry may include any appropriate chemistry for the materials to be used such as but not limited to reactive ion etch (RIE) for the dielectric layers of peripheral region 108. Mask 180 may be removed using any appropriate removal process, such as an ashing process.

FIG. 16 shows forming a dielectric layer 186 over substrate 104, i.e., over regions 106, 112, 114 and 122. Dielectric layer 186 may include one or more materials, and may be formed using any appropriate deposition technique, e.g., chemical vapor deposition, for the materials used. As described herein, dielectric layer 186 may include the materials listed herein for passivation layer 140 and first dielectric liners 134, 152. For example, as shown in FIG. 3, dielectric layer 186 may include silicon nitride layer 142 over silicon oxide layer 144. Dielectric layer 186 forms first dielectric liner 134 and second dielectric liner 152. Dielectric layer 186 forming also forms air gap 132 in first dielectric liner 134 in first continuous DT 130, i.e., by pinching off the upper end of first continuous DT 130. Where provided, dielectric layer 186 forming also forms second dielectric liner 152 in second continuous DT 150. Second continuous DT 150 has sufficient width, however, that it continues to have open upper end 154.

FIG. 16 also shows forming an opening 190 in passivation layer 140 for conductive member 170 (FIG. 8) at upper surface 124 of IC region 106 and in contact with last metal layer 119 of BEOL interconnect stack 118. Opening 190 may be formed using any desired photolithography processing, e.g., forming and patterning a mask and etching to remove material. Conductive member 170 may be formed by depositing any appropriate material, e.g., copper or aluminum with a refractory metal liner, and planarizing (e.g., using chemical mechanical polishing) to form a conductive wire or line in contact with last metal layer 119 of IC region 106. Contact pads (not shown) may be made over conductive member 170 (FIG. 8) in any now known or later developed fashion. It will be recognized that, where provided, second continuous DT 150 may be removed during dicing of IC chips 102.

Embodiments of the disclosure provide various technical and commercial advantages, examples of which are discussed herein. The structures described herein provide a moisture barrier and crack stop structure in a manner that does not include segmentation or breaks therein. The structures are not expensive to add and are advantageous for, for example, radio frequency (RF) circuit applications. As noted, the structures may also optionally include a segmented metal seal ring and/or another open-ended deep trench.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure, comprising:
an integrated circuit (IC) chip including an IC region and a peripheral region around the IC region;
a first continuous deep trench (DT) defined in the peripheral region around the IC region; and
an air gap defined by a first dielectric liner in the first continuous DT.

2. The structure of claim 1, further comprising:
a second continuous deep trench (DT) defined in a scribe region of the peripheral region around the first continuous DT; and
a second dielectric liner in the second continuous DT,
wherein the second continuous DT has an open upper end.

3. The structure of claim 2, further comprising a segmented metal seal ring between the first continuous DT and the second continuous DT.

4. The structure of claim 2, wherein the first continuous DT has a maximum width, excluding the first dielectric liner, in a range of 1.0 to 1.5 micrometers, and the second continuous DT has a maximum width, excluding the second dielectric liner, in a range of 6 to 30 micrometers.

5. The structure of claim 2, wherein the first continuous DT includes a plurality of first continuous DTs that are concentrically arranged.

6. The structure of claim 1, wherein the first dielectric liner includes a silicon nitride layer over a silicon oxide layer.

7. The structure of claim 1, wherein the first dielectric liner is contiguous with a passivation layer over the IC chip, and the air gap has an upper end at least covered by the passivation layer.

8. The structure of claim 1, wherein the first continuous DT has a maximum width, excluding the air gap, in a range of 1.0 to 1.5 micrometers, and the air gap has a maximum width in a range of 0.2 to 0.5 micrometers.

9. The structure of claim 1, wherein the first continuous DT includes a plurality of first continuous DTs that are concentrically arranged.

10. The structure of claim 1, wherein the first continuous DT extends vertically along an entirety of a back-end-of-line (BEOL) interconnect stack in the IC region.

11. The structure of claim 1, wherein the peripheral region is devoid of any other moisture barrier or crack stop structures other than the air gap in the first dielectric liner.

12. A protective moisture barrier and crack stop structure for an integrated circuit (IC) chip including an IC region, a peripheral region around the IC region and a back-end-of-line (BEOL) interconnect stack in the IC chip, the structure comprising:
a first continuous deep trench (DT) defined in the peripheral region around the IC region; and
an air gap defined by a first dielectric liner in the first continuous DT,
wherein the first continuous DT extends vertically along an entirety of the BEOL interconnect stack in the IC region,
wherein the peripheral region is devoid of any other moisture barrier or crack stop structures.

13. The protective moisture barrier and crack stop structure of claim 12, further comprising:
a second continuous deep trench (DT) defined in a scribe region of the peripheral region around the first continuous DT; and
a second dielectric liner in the second continuous DT,
wherein the second continuous DT has an open upper end,
wherein the first continuous DT has a maximum width smaller than that of the second continuous DT.

14. The protective moisture barrier and crack stop structure of claim 13, further comprising a segmented metal seal ring between the first continuous DT and the second continuous DT.

15. The protective moisture barrier and crack stop structure of claim 12, wherein the first continuous DT has a maximum width, excluding the air gap, in a range of 1.0 to 1.5 micrometers, and the air gap has a maximum width in a range of 0.2 to 0.5 micrometers.

16. The protective moisture barrier and crack stop structure of claim 12, wherein the first continuous DT includes a plurality of first continuous DTs with the air gap therein that are concentrically arranged.

17. A method, comprising:
in a semiconductor substrate including a plurality of integrated circuit (IC) chips, each IC chip including an IC region and a peripheral region around the IC region, wherein the IC region includes a back-end-of-line (BEOL) interconnect stack:
forming a first continuous deep trench (DT) defined in the peripheral region around the IC region, wherein the first continuous DT extends vertically along an entirety of the BEOL interconnect stack in the IC region; and
forming a dielectric layer over the semiconductor substrate, the dielectric layer forming also forming an air gap in a first dielectric liner in the first continuous DT.

18. The method of claim 17, further comprising:
forming a second continuous deep trench (DT) defined in the peripheral region around the first continuous DT, and wherein forming the dielectric layer forms a second dielectric liner in the second continuous DT, wherein the second continuous DT has an open upper end.

19. The method of claim 18, further comprising forming a segmented metal seal ring between the first continuous DT and the second continuous DT.

20. The method of claim 17, wherein forming the first continuous DT includes forming a plurality of first continuous DTs that are concentrically arranged.
